(19) United States
(12) Patent Application Publication
(10) Pub. No.: US 2025/0159838 A1
(43) Pub. Date: May 15, 2025

(54) SMALL WATER CHILLER FOR WATER CIRCULATION IN DATA CENTER

(71) Applicant: Hebei Qinhuai Data Co., Limited., Zhangjiakou City, Hebei Province (CN)

(72) Inventor: Binghua ZHANG, Zhangjiakou City (CN)

(21) Appl. No.: 18/939,469

(22) Filed: Nov. 6, 2024

(30) Foreign Application Priority Data
Nov. 15, 2023 (CN) 202311525784.5

(51) Int. Cl. H05K 7/20

(52) U.S. Cl. CPC H05K 7/20263; H05K 7/20272; H05K 7/2079

(57) ABSTRACT

The present disclosure discloses a small water chiller for water circulation in a data center, which includes a data center and a machine room floor. An auxiliary bracket touching the machine room floor is mounted at a bottom of the data center, and a closed heat transfer cylinder is nested inside a corner of the data center. A cooling trough positioned at a rear end of the data center is provided on the machine room floor. Inside the cooling trough there is sleeved with a capsular cold water component, a limit support plate, a support shaft, an inclined pressure-regulating plate, an outlet one-way valve tube, and a reflux one-way valve tube.

### CROSS REFERENCE TO RELATED APPLICATION

This application claims priority to Chinese Patent Application No. 202311525784.5, titled “SMALL WATER CHILLER FOR WATER CIRCULATION IN DATA CENTER” and filed to the China National Intellectual Property Administration on Nov. 15, 2023, the entire contents of which are incorporated herein by reference.

### TECHNICAL FIELD

The present disclosure relates to the technical field of small water chiller for water circulation, and more particularly, to a small water chiller for water circulation in a data center.

### BACKGROUND

As globally collaborative specific network equipment, a data center is used to transmit, accelerate, display, compute, and store data information on network infrastructure. Emergence of the data center guides people's understanding from a quantitative and structured world to an uncertain and nonstructured world. It will gradually become a part of modern social infrastructure, just like transportation and network communication, and has a positive impact on many industries.

At present, when in use, to ensure smooth and safe operation of the data center, generally corresponding cooling measures may be taken. For example, an existing water circulation refrigeration system is used, which is a refrigeration system mainly comprised of a cooling tower, a cooling water circulation pump, a water chilling unit, and a cold water circulation pump to refrigerate environment where the data center is positioned. Relevant technologies have also been disclosed, such as the authorized patent with a publication number CN214413341U, which provides a detailed introduction to water circulation cooling technologies for the refrigeration system of the data center.

However, from the specific technical contents mentioned above, the existing technologies in refrigeration of the data center tend to focus on overall temperature control of the environment where the data center is positioned and synchronous program temperature control of a plurality of data centers. However, this requires stable and extensive power support to ensure stable operation. In the event of emergency situations such as sudden failure of large cooling equipment or power shortage, although operation of the data center can be ensure, there is a lack of effective and targeted technological refrigeration means to cope with the emergency situations. Thus, there are obvious technical defects in the existing refrigeration technologies.

### SUMMARY

The present disclosure provides a small water chiller for water circulation in a data center, which solves the problems raised in the background technology mentioned above.

The present disclosure provides the following technical solutions. The small water chiller for water circulation in the data center includes a data center and a machine room floor, where an auxiliary bracket touching the machine room floor is mounted at a bottom of the data center. A closed heat transfer cylinder is nested inside a corner of the data center, and a cooling trough positioned at a rear end of the data center is provided on the machine room floor. Inside the cooling trough there is sleeved with a capsular cold water component, a limit support plate, a support shaft, an inclined pressure-regulating plate, an outlet one-way valve tube, and a reflux one-way valve tube. The capsular cold water component is internally sleeved with a first reset spring, and a bottom of the capsular cold water component is provided with a receiving cavity, which is provided with a small water chiller for refrigerating a cooling liquid inside the capsular cold water component. A middle of the support shaft is attached into a side of the inclined pressure-regulating plate by means of a bearing.

An end of the outlet one-way valve tube and an end of the reflux one-way valve tube are connected to a liquid transport composite pipe fitting and a reflux composite pipe fitting, respectively. An output end of the liquid transport composite pipe fitting and an input end of the reflux composite pipe fitting extend and attach to a bottom and a top of the closed heat transfer cylinder, respectively. Other end of the outlet one-way valve tube and other end of the reflux one-way valve tube extend and attach to two sides of the capsular cold water component, respectively.

An outer side on a top of the reflux composite pipe fitting is provided with a pressure-exerting rod piece and a power output component, where an output structure of the power output component is connected to an end of the pressure-exerting rod piece in a transmission way, and other end of the pressure-exerting rod piece extends to a surface in a middle of the inclined pressure-regulating plate for adhesive connection.

Preferably, a surface on a top of the capsular cold water component is glued and fixed to a surface on a bottom of the limit support plate, two sides of the limit support plate are fixed to an inner wall of the cooling trough by means of a screw; and a bottom surface of the capsular cold water component is adhered and connected to an inner wall on a bottom of a demising trough.

Preferably; the liquid transport composite pipe fitting includes a main liquid transport tube, a first annular tube, and a first branch tube. An end of the main liquid transport tube and an end of the first branch tube are both attached to the first annular tube, other end of the main liquid transport tube is connected to an end of the outlet one-way valve tube, and other end of the first branch tube is used as the output end of the liquid transport composite pipe fitting and is attached onto the bottom of the closed heat transfer cylinder.

Preferably, the reflux composite pipe fitting includes a main reflux tube, a second annular tube, and a second branch tube. An end of the main reflux tube and an end of the second branch tube are both attached to the second annular tube, other end of the main reflux tube is connected to an end of the reflux one-way valve tube, and other end of the second branch tube is used as the input end of the reflux composite pipe fitting and is attached onto the top of the closed heat transfer cylinder.

Preferably; the pressure-exerting rod piece includes a curved support rod, a pressure-exerting sleeve roller, and a linkage rod. A side of the curved support rod is attached to an inner side in a middle of the pressure-exerting sleeve roller by means of a bearing, other side of the curved support rod is welded and fixed to an end of the linkage rod, and a surface of the pressure-exerting sleeve roller is adhered and connected to a surface in a middle of the inclined pressure-regulating plate.

Preferably, an outer side of the power output component is covered with a semi-open protective shell. The power output component includes a hydraulic rod and a transition rod, where an output end of the hydraulic rod is connected to an end of the transition rod in a transmission way. The transition rod is used as an output structure of the power output component and is connected to other end of the linkage rod in a transmission way, and a support seat is installed between a housing of the hydraulic rod and a top of the machine room floor.

Preferably, an end of the transition rod and the other end of the linkage rod are both flange structures and are fixed by means of a screw; other end of the transition rod and the output end of the hydraulic rod are both flange structures and are fixed by means of a screw. A T-shaped rod is welded and fixed on a surface in a middle of the transition rod, two ends of the T-shaped rod far away from the transition rod are both flange structures, and the T-shaped rod is movably sleeved in the semi-open protective shell.

Preferably, an end of the linkage rod is internally provided with a stepped hole, an end of the stepped hole is provided with an internal thread, and a surface at the other end of the linkage rod is welded and fixed to a handle. An outer side at an end of the linkage rod is provided with a composite screw and a lever bracket, where an end of the composite screw is in threaded connection inside the stepped hole, a top of the lever bracket is provided with a positioning hole aligned with the composite screw; and a bottom of the lever bracket is fixed on the machine room floor. The composite screw is comprised of a nut and a first threaded rod and a second threaded rod fixedly connected to two ends of the nut, respectively. The nut is in threaded connection inside the stepped hole, and the first threaded rod is movably sleeved in the stepped hole.

Preferably, the bottom of the lever bracket is provided with an annular airbag, where a surface of the annular airbag is glued and installed on the inner wall of the cooling trough, and the annular airbag is internally sleeved with a second reset spring. A top of the annular airbag is sleeved with an intake one-way valve tube and an air transmission composite pipe fitting, and an output end of the air transmission composite pipe fitting is connected to a heat transfer pipe, where the heat transfer pipe is fixedly sleeved inside the closed heat transfer cylinder, and two ends of the heat transfer pipe both protrude to an outer side of the closed heat transfer cylinder.

Preferably, the air transmission composite pipe fitting includes a main air transmission pipe, an arc-shaped pipe, and an air transmission branch tube. An end of the main air transmission pipe and an end of the air transmission branch tube are both attached to the arc-shaped pipe, other end of the main air transmission pipe extends and attaches to an inner side on a top of the annular airbag, other end of the air transmission branch tube is used as an output end of the air transmission composite pipe fitting and is attached onto a bottom of the heat transfer pipe, and an inner side of the heat transfer pipe is fixedly sleeved with a heat transfer sheet.

The present disclosure has the following beneficial effects.

1. In the present disclosure, the capsular cold water component, the outlet one-way valve tube, the liquid transport composite pipe fitting, the closed heat transfer cylinder, the reflux composite pipe fitting and the reflux one-way valve tube are arranged to constitute an integrated small water chiller for passive water circulation. The support shaft, the inclined pressure-regulating plate, the pressure-exerting rod piece and the power output component are arranged to constitute a pressure-exerting structure. The integrated water chiller is used in combination with the pressure-exerting structure, to achieve water circulation cooling of the data center, spontaneous heat dissipation by means of the large-area machine room floor, and auxiliary cooling of the small water chiller, thereby fully ensuring continuous circulation cooling effects of the data center. Compared with existing large cooling equipment, the device provided in the present disclosure can ensure smooth operation of the data center in emergency situations and solve the problems of the existing technologies.

2. In the present disclosure, by adjusting a connection manner of the power output component, the integrated small water chiller for passive water circulation and the pressure-exerting structure can be operated manually to cool the data center through water circulation and cope with power shortage, which further expands functional application scope of the overall device.

3. In the present disclosure, an annular airbag, an air transmission composite pipe fitting, a heat transfer pipe and a heat transfer sheet are arranged to form an air blast cooling structure, and deformation operation of the integrated small water chiller for water circulation is linked to perform air blast cooling of the cooling liquid in the water circulation, thereby accelerating self heat dissipation speed of the cooling liquid, which further optimizes lasting effects in circulation cooling of the data center.

### BRIEF DESCRIPTION OF THE DRAWINGS

FIG. 1 is a schematic front view of a data center according to the present disclosure;

FIG. 2 is a schematic rear view of the data center according to the present disclosure;

FIG. 3 is a schematic top view according to Embodiment I of the present disclosure;

FIG. 4 is a schematic partial enlarged diagram of a closed heat transfer cylinder according to the present disclosure;

FIG. 5 is a schematic enlarged diagram of a cooling liquid bladder according to the present disclosure;

FIG. 6 is a schematic top view according to Embodiment II of the present disclosure;

FIG. 7 is a schematic partial sectional view of a lever bracket according to the present disclosure;

FIG. 8 is a schematic enlarged diagram of a composite screw according to the present disclosure;

FIG. 9 is a schematic front view according to Embodiment III of the present disclosure;

FIG. 10 is a schematic top view according to Embodiment III of the present disclosure;

FIG. 11 is a schematic enlarged diagram of an annular airbag according to the present disclosure;

FIG. 12 is a schematic partial sectional diagram of a heat transfer pipe according to the present disclosure; and

FIG. 13 is a schematic upward view of a capsular cold water component according to the present disclosure.

Reference numerals in the accompanying drawings: data center 1; machine room floor 2; closed heat transfer cylinder 3; 4. capsular cold water component; limit support plate 5; support shaft 6; inclined pressure-regulating plate 7; outlet one-way valve tube 8; reflux one-way valve tube 9; liquid transport composite pipe fitting 10; main liquid transport tube 101; first annular tube 102; first branch tube 103; reflux composite pipe fitting 11; main reflux tube 111; second annular tube 112; second branch tube 113; pressure-exerting rod piece 12; curved support rod 121; pressure-exerting sleeve roller 122; linkage rod 123; power output component 13; hydraulic rod 131; transition rod 132; composite screw 14; nut 141; first threaded rod 142; second threaded rod 143; lever bracket 15; annular airbag 16; air transmission composite pipe fitting 17; main air transmission pipe 171; arc-shaped pipe 172; air transmission branch tube 173; heat transfer pipe 18; and heat transfer sheet 19.

### DETAILED DESCRIPTION

Technical solutions in the embodiments of the present disclosure will be described clearly and completely below; in conjunction with the accompanying drawings in the embodiments of the present disclosure. Apparently; the described embodiments are some but not all of the embodiments of the present disclosure. All other embodiments obtained by those of ordinary skills in the art based on the embodiments of the present disclosure without creative efforts shall fall within the protection scope of the present disclosure.

### Embodiment I

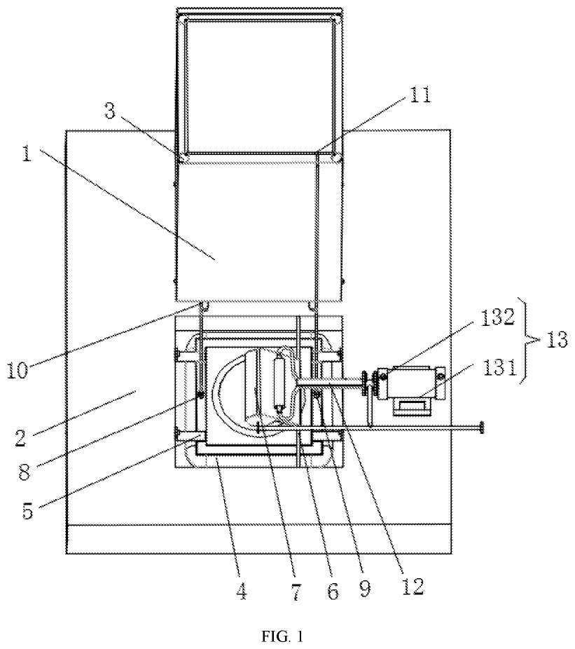

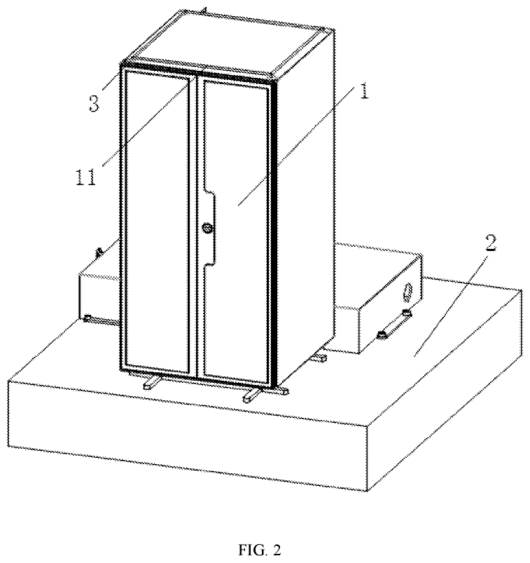

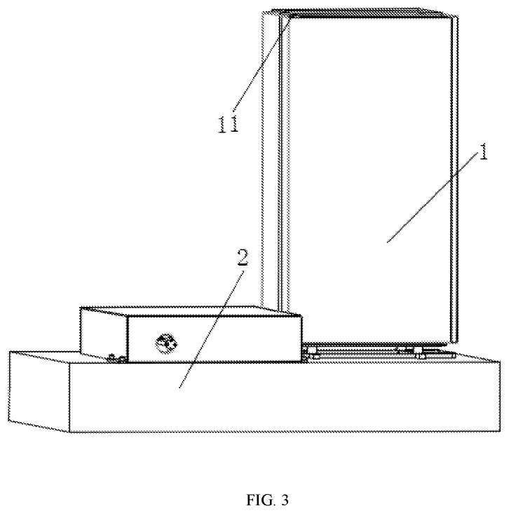

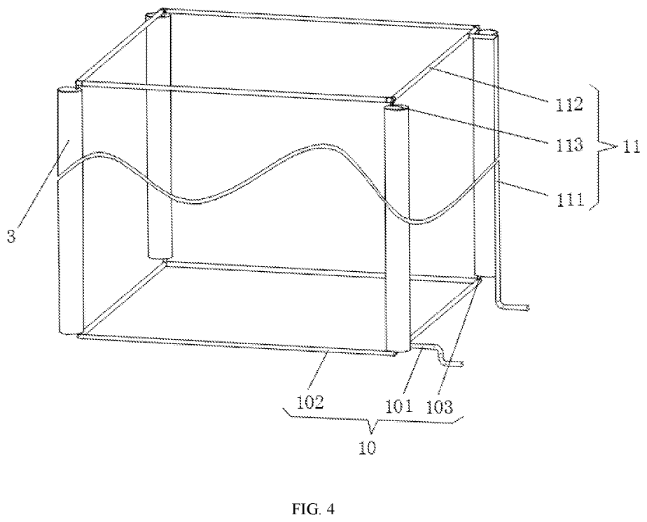

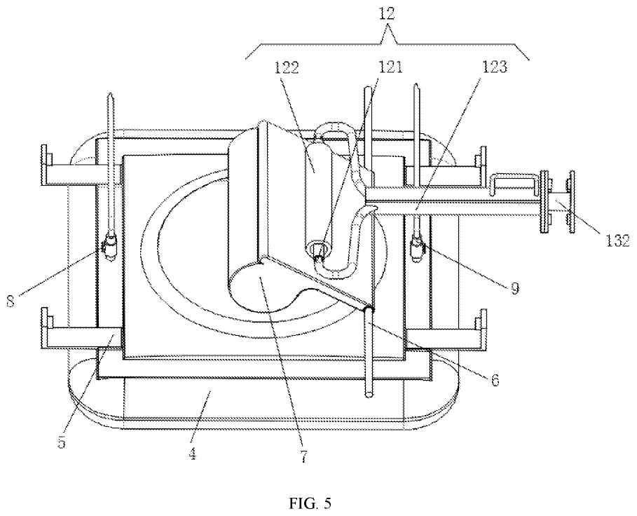

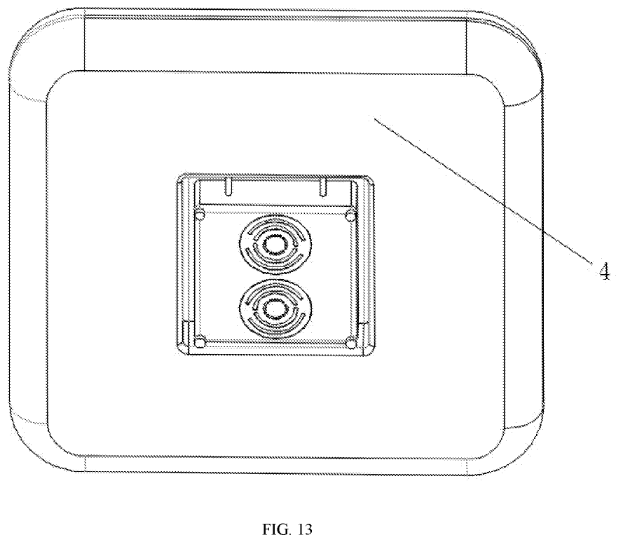

Referring to FIGS. 1 to 5 and FIG. 13, a small water chiller for water circulation in a data center includes a data center 1 and a machine room floor 2, where an auxiliary bracket touching the machine room floor 2 is mounted at a bottom of the data center 1. A closed heat transfer cylinder 3 is nested inside a corner of the data center 1, and a cooling trough positioned at a rear end of the data center 1 is provided on the machine room floor 2. Inside the cooling trough there is sleeved with a capsular cold water component 4, a limit support plate 5, a support shaft 6, an inclined pressure-regulating plate 7, an outlet one-way valve tube 8, and a reflux one-way valve tube 9. The capsular cold water component 4 is internally sleeved with a first reset spring, and a bottom of the capsular cold water component 4 is provided with a receiving cavity, which is provided with a small water chiller for refrigerating a cooling liquid inside the capsular cold water component 4. A middle of the support shaft 6 is attached into a side of the inclined pressure-regulating plate 7 by means of a bearing.

A surface on a top of the capsular cold water component 4 is glued and fixed to a surface on a bottom of the limit support plate 5, and two sides of the limit support plate 5 are fixed to an inner wall of the cooling trough by means of a screw; making it convenient for subsequent disassembly. A bottom surface of the capsular cold water component 4 is adhered and connected to an inner wall on a bottom of a demising trough. Both the top and the bottom of the capsular cold water component 4 are limited, which causes lateral deformation buffering of the capsular cold water component 4 after it is compressed.

An end of the outlet one-way valve tube 8 and an end of the reflux one-way valve tube 9 are connected to a liquid transport composite pipe fitting 10 and a reflux composite pipe fitting 11, respectively. An output end of the liquid transport composite pipe fitting 10 and an input end of the reflux composite pipe fitting 11 extend and attach to a bottom and a top of the closed heat transfer cylinder 3, respectively. Other end of the outlet one-way valve tube 8 and other end of the reflux one-way valve tube 9 extend and attach to two sides of the capsular cold water component 4, respectively.

The liquid transport composite pipe fitting 10 includes a main liquid transport tube 101, a first annular tube 102, and a first branch tube 103. An end of the main liquid transport tube 101 and an end of the first branch tube 103 are both attached to the first annular tube 102, other end of the main liquid transport tube 101 is connected to an end of the outlet one-way valve tube 8, and other end of the first branch tube 103 is used as the output end of the liquid transport composite pipe fitting 10 and is attached onto the bottom of the closed heat transfer cylinder 3. The reflux composite pipe fitting 11 includes a main reflux tube 111, a second annular tube 112, and a second branch tube 113. An end of the main reflux tube 111 and an end of the second branch tube 113 are both attached to the second annular tube 112, other end of the main reflux tube 111 is connected to an end of the reflux one-way valve tube 9, and other end of the second branch tube 113 is used as the input end of the reflux composite pipe fitting 11 and is attached onto the top of the closed heat transfer cylinder 3. The liquid transport composite pipe fitting 10 and the reflux composite pipe fitting 11 are structurally linked to the outlet one-way valve tube 8, the reflux one-way valve tube 9 and the capsular cold water component 4, to form a circulation channel for subsequent water circulation.

An outer side on a top of the reflux composite pipe fitting 11 is provided with a pressure-exerting rod piece 12 and a power output component 13, where an output structure of the power output component 13 is connected to an end of the pressure-exerting rod piece 12 in a transmission way, and other end of the pressure-exerting rod piece 12 extends to a surface in a middle of the inclined pressure-regulating plate 7 for adhesive connection.

The pressure-exerting rod piece 12 includes a curved support rod 121, a pressure-exerting sleeve roller 122, and a linkage rod 123. A side of the curved support rod 121 is attached to an inner side in a middle of the pressure-exerting sleeve roller 122 by means of a bearing, and other side of the curved support rod 121 is welded and fixed to an end of the linkage rod 123. A surface of the pressure-exerting sleeve roller 122 is adhered and connected to a surface in a middle of the inclined pressure-regulating plate 7. An outer side of the power output component 13 is covered with a semi-open protective shell. The power output component 13 includes a hydraulic rod 131 and a transition rod 132, where an output end of the hydraulic rod 131 is connected to an end of the transition rod 132 in a transmission way, and the transition rod 132 is used as an output structure of the power output component 13 and is connected to other end of the linkage rod 123 in a transmission way. A support seat is installed between a housing of the hydraulic rod 131 and a top of the machine room floor 2. The pressure-exerting rod piece 12 and the power output component 13 are combined to automatically exert pressure on the inclined pressure-regulating plate 7, and then the inclined pressure-regulating plate 7 synchronously exerts pressure on the capsular cold water component 4, allowing the cooling liquid inside the capsular cold water component 4 to flow in the circulation channel, to assist the closed heat transfer cylinder 3 in direct and targeted cooling of the data center 1 through water circulation.

Operating principles are as below. In the event of sudden failure of large cooling equipment, the hydraulic rod 131 inside the power output component 13 reciprocates, such that the output end of the hydraulic rod 131 drives, through the transition rod 132, the pressure-exerting rod piece 12 to carry out reciprocating rectilinear top pressure movement at the top of the inclined pressure-regulating plate 7, causing the inclined pressure-regulating plate 7 to exert reciprocating extrusion on the capsular cold water component 4.

When the capsular cold water component 4 is subjected to periodic extrusion, the cooling liquid inside the capsular cold water component 4 will incessantly enter the liquid transport composite pipe fitting 10 through the outlet one-way valve tube 8, and then enter the closed heat transfer cylinder 3. Next, internal heat generated by the data center 1 during operation is transferred by means of the closed heat transfer cylinder 3 and the cooling liquid. After internal space of the closed heat transfer cylinder 3 is filled up, the cooling liquid that absorbs a certain amount of heat will flow back to the capsular cold water component 4 through the reflux composite pipe fitting 11 and the reflux one-way valve tube 9. In this way; the direct and targeted cooling of the data center 1 is achieved through water circulation.

Each time when the capsular cold water component 4 is pressed and tiled, the small water chiller is not extruded, and the small water chiller is selected from technical products from Yingshang Toudengcang Technology Development Co., Ltd., and the cooling liquid inside the capsular cold water component 4 contacts the machine room floor 2 at maximum area. Next, the large-area machine room floor 2 and the small water chiller are used to achieve their own cooling, to meet continuous use effects based on water circulation cooling.

### Embodiment II

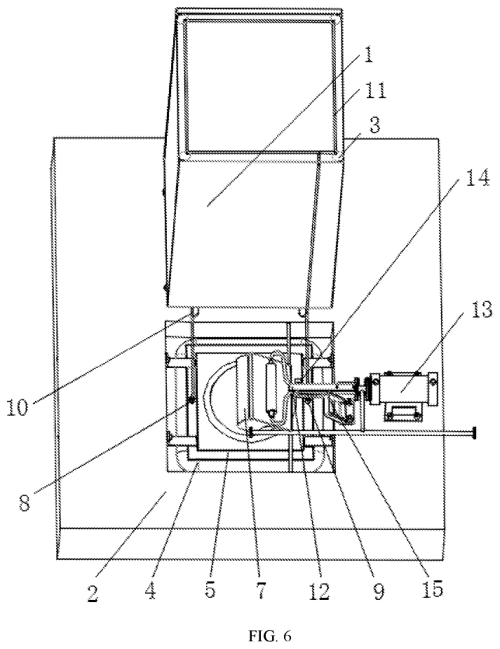

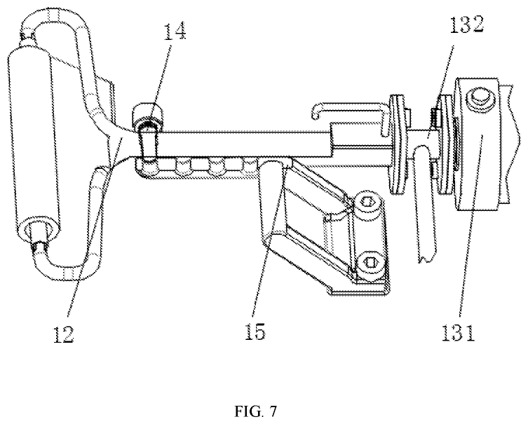

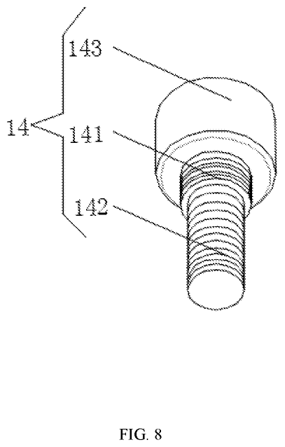

Referring to FIGS. 6 to 8 and FIG. 13, a small water chiller for water circulation in a data center includes a data center 1 and a machine room floor 2, where an auxiliary bracket touching the machine room floor 2 is mounted at a bottom of the data center 1. A closed heat transfer cylinder 3 is nested inside a corner of the data center 1, and a cooling trough positioned at a rear end of the data center 1 is provided on the machine room floor 2. Inside the cooling trough there is sleeved with a capsular cold water component 4, a limit support plate 5, a support shaft 6, an inclined pressure-regulating plate 7, an outlet one-way valve tube 8, and a reflux one-way valve tube 9. The capsular cold water component 4 is internally sleeved with a first reset spring, and a bottom of the capsular cold water component 4 is provided with a receiving cavity, which is provided with a small water chiller for refrigerating a cooling liquid inside the capsular cold water component 4. A middle of the support shaft 6 is attached into a side of the inclined pressure-regulating plate 7 by means of a bearing.

A surface on a top of the capsular cold water component 4 is glued and fixed to a surface on a bottom of the limit support plate 5, and two sides of the limit support plate 5 are fixed to an inner wall of the cooling trough by means of a screw; making it convenient for subsequent disassembly. A bottom surface of the capsular cold water component 4 is adhered and connected to an inner wall on a bottom of a demising trough. Both the top and the bottom of the capsular cold water component 4 are limited, which causes lateral deformation buffering of the capsular cold water component 4 after it is compressed.

An end of the outlet one-way valve tube 8 and an end of the reflux one-way valve tube 9 are connected to a liquid transport composite pipe fitting 10 and a reflux composite pipe fitting 11, respectively. An output end of the liquid transport composite pipe fitting 10 and an input end of the reflux composite pipe fitting 11 extend and attach to a bottom and a top of the closed heat transfer cylinder 3, respectively. Other end of the outlet one-way valve tube 8 and other end of the reflux one-way valve tube 9 extend and attach to two sides of the capsular cold water component 4, respectively.

The liquid transport composite pipe fitting 10 includes a main liquid transport tube 101, a first annular tube 102, and a first branch tube 103. An end of the main liquid transport tube 101 and an end of the first branch tube 103 are both attached to the first annular tube 102, other end of the main liquid transport tube 101 is connected to an end of the outlet one-way valve tube 8, and other end of the first branch tube 103 is used as the output end of the liquid transport composite pipe fitting 10 and is attached onto the bottom of the closed heat transfer cylinder 3. The reflux composite pipe fitting 11 includes a main reflux tube 111, a second annular tube 112, and a second branch tube 113. An end of the main reflux tube 111 and an end of the second branch tube 113 are both attached to the second annular tube 112, other end of the main reflux tube 111 is connected to an end of the reflux one-way valve tube 9, and other end of the second branch tube 113 is used as the input end of the reflux composite pipe fitting 11 and is attached onto the top of the closed heat transfer cylinder 3. The liquid transport composite pipe fitting 10 and the reflux composite pipe fitting 11 are structurally linked to the outlet one-way valve tube 8, the reflux one-way valve tube 9 and the capsular cold water component 4, to form a circulation channel for subsequent water circulation.

An outer side on a top of the reflux composite pipe fitting 11 is provided with a pressure-exerting rod piece 12 and a power output component 13, where an output structure of the power output component 13 is connected to an end of the pressure-exerting rod piece 12 in a transmission way, and other end of the pressure-exerting rod piece 12 extends to a surface in a middle of the inclined pressure-regulating plate 7 for adhesive connection.

The pressure-exerting rod piece 12 includes a curved support rod 121, a pressure-exerting sleeve roller 122, and a linkage rod 123. A side of the curved support rod 121 is attached to an inner side in a middle of the pressure-exerting sleeve roller 122 by means of a bearing, and other side of the curved support rod 121 is welded and fixed to an end of the linkage rod 123. A surface of the pressure-exerting sleeve roller 122 is adhered and connected to a surface in a middle of the inclined pressure-regulating plate 7. An outer side of the power output component 13 is covered with a semi-open protective shell. The power output component 13 includes a hydraulic rod 131 and a transition rod 132, where an output end of the hydraulic rod 131 is connected to an end of the transition rod 132 in a transmission way, and the transition rod 132 is used as an output structure of the power output component 13 and is connected to other end of the linkage rod 123 in a transmission way. A support seat is installed between a housing of the hydraulic rod 131 and a top of the machine room floor 2. The pressure-exerting rod piece 12 and the power output component 13 are combined to automatically exert pressure on the inclined pressure-regulating plate 7, and then the inclined pressure-regulating plate 7 synchronously exerts pressure on the capsular cold water component 4, allowing the cooling liquid inside the capsular cold water component 4 to flow in the circulation channel, to assist the closed heat transfer cylinder 3 in direct and targeted cooling of the data center 1 through water circulation.

An end of the transition rod 132 and the other end of the linkage rod 123 are both flange structures and are fixed by means of a screw; and other end of the transition rod 132 and the output end of the hydraulic rod 131 are both flange structures and are fixed by means of a screw. Detachable use of the two ends of transition rod 132 will provide conditions for independent use of the pressure-exerting rod piece 12.

A T-shaped rod is welded and fixed on a surface in a middle of the transition rod 132, where two ends of the T-shaped rod far away from the transition rod 132 are both flange structures, and the T-shaped rod is movably sleeved in the semi-open protective shell. By arranging the T-shaped rod, the power output component 13 may be allowed to link a plurality of pressure-exerting rod pieces 12 when needed, to perform synchronous operation of a plurality of power structures with a single power source. In this way, usage costs in cooling a plurality of data centers 1 can be reduced while the use effects are optimized.

An end of the linkage rod 123 is internally provided with a stepped hole, and an end of the stepped hole is provided with an internal thread. A surface at the other end of the linkage rod 123 is welded and fixed to a handle, and an outer side at an end of the linkage rod 123 is provided with a composite screw 14 and a lever bracket 15. An end of the composite screw 14 is in threaded connection inside the stepped hole, a top of the lever bracket 15 is provided with a positioning hole aligned with the composite screw 14, and a bottom of the lever bracket 15 is fixed on the machine room floor 2. The composite screw 14 is comprised of a nut 141 and a first threaded rod 142 and a second threaded rod 143 fixedly connected to two ends of the nut 141, respectively. The nut 141 is in threaded connection inside the stepped hole, and the first threaded rod 142 is movably sleeved in the stepped hole. The lever bracket 15 is combined with the composite screw 14 and is linked to the pressure-exerting rod piece 12, such that the pressure-exerting rod piece 12 can perform a pressure-exerting operation manually. In this way, overall performance of the device in coping with extreme situations can be improved.

Operating principles are as below. In the event of an emergency situation such as power shortage, screws at two ends of the transition rod 132 in the power output component 13 are unscrewed and the transition rod 132 is dismantled. Next, the composite screw 14 is installed in the stepped hole of the linkage rod 123 in a threaded locking manner to form limit locking. The first threaded rod 142 inside the composite screw 14 extends into the positioning hole, with its end stretching out. The threaded locking is achieved by means of the nut and the stretching end of the first threaded rod 142, to meet the limit requirements.

After the above installation and adjustment are completed, the pressure-exerting rod piece 12 is lifted in a reciprocating lever manner by means of support of the lever bracket 15 and the composite screw 14 by gripping the handle, such that the pressure-exerting rod piece 12 squeezes the inclined pressure-regulating plate 7 and the capsular cold water component 4 back and forth.

When the capsular cold water component 4 is subjected to periodic extrusion, the cooling liquid inside the capsular cold water component 4 will incessantly enter the liquid transport composite pipe fitting 10 through the outlet one-way valve tube 8, and then enter the closed heat transfer cylinder 3. Next, internal heat generated by the data center 1 during operation is transferred by means of the closed heat transfer cylinder 3 and the cooling liquid. After internal space of the closed heat transfer cylinder 3 is filled up, the cooling liquid that absorbs a certain amount of heat will flow back to the capsular cold water component 4 through the reflux composite pipe fitting 11 and the reflux one-way valve tube 9. In this way; the direct and targeted cooling of the data center 1 is achieved through water circulation.

Each time when the capsular cold water component 4 is pressed and tiled, the small water chiller is not extruded, and the small water chiller is selected from technical products from Yingshang Toudengcang Technology Development Co., Ltd., and the cooling liquid inside the capsular cold water component 4 contacts the machine room floor 2 at maximum area. Next, the large-area machine room floor 2 and the small water chiller are used to achieve their own cooling, to meet continuous use effects based on water circulation cooling.

### Embodiment III

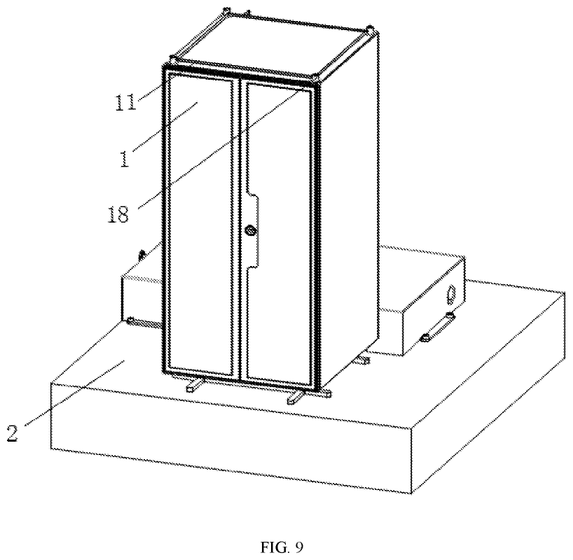

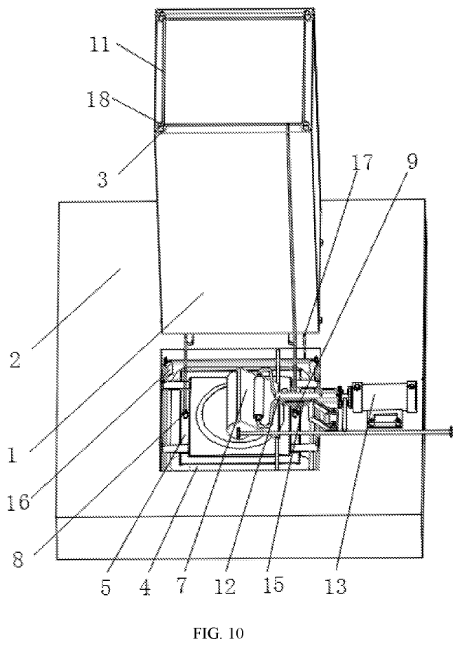

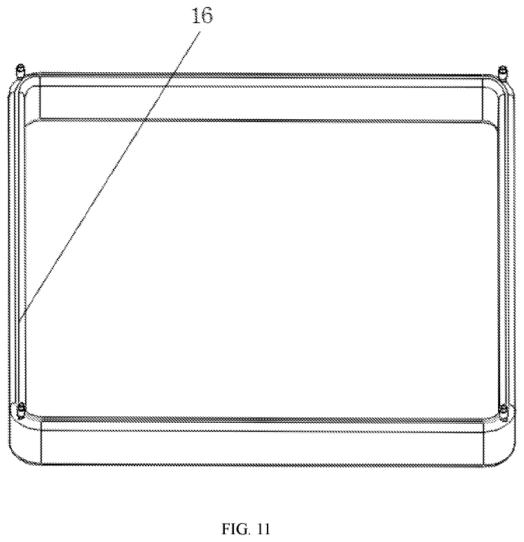

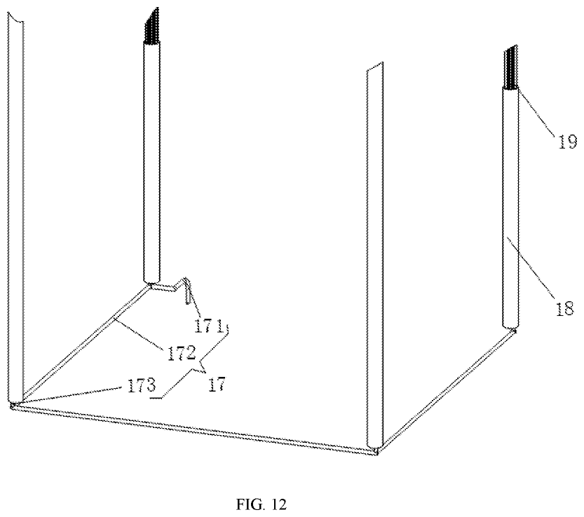

Referring to FIGS. 9 to 12, a small water chiller for water circulation in a data center includes a data center 1 and a machine room floor 2, where an auxiliary bracket touching the machine room floor 2 is mounted at a bottom of the data center 1. A closed heat transfer cylinder 3 is nested inside a corner of the data center 1, and a cooling trough positioned at a rear end of the data center 1 is provided on the machine room floor 2. Inside the cooling trough there is sleeved with a capsular cold water component 4, a limit support plate 5, a support shaft 6, an inclined pressure-regulating plate 7, an outlet one-way valve tube 8, and a reflux one-way valve tube 9. The capsular cold water component 4 is internally sleeved with a first reset spring, and a bottom of the capsular cold water component 4 is provided with a receiving cavity, which is provided with a small water chiller for refrigerating a cooling liquid inside the capsular cold water component 4. A middle of the support shaft 6 is attached into a side of the inclined pressure-regulating plate 7 by means of a bearing.

A surface on a top of the capsular cold water component 4 is glued and fixed to a surface on a bottom of the limit support plate 5, and two sides of the limit support plate 5 are fixed to an inner wall of the cooling trough by means of a screw; making it convenient for subsequent disassembly. A bottom surface of the capsular cold water component 4 is adhered and connected to an inner wall on a bottom of a demising trough. Both the top and the bottom of the capsular cold water component 4 are limited, which causes lateral deformation buffering of the capsular cold water component 4 after it is compressed.

An end of the outlet one-way valve tube 8 and an end of the reflux one-way valve tube 9 are connected to a liquid transport composite pipe fitting 10 and a reflux composite pipe fitting 11, respectively. An output end of the liquid transport composite pipe fitting 10 and an input end of the reflux composite pipe fitting 11 extend and attach to a bottom and a top of the closed heat transfer cylinder 3, respectively. Other end of the outlet one-way valve tube 8 and other end of the reflux one-way valve tube 9 extend and attach to two sides of the capsular cold water component 4, respectively.

The liquid transport composite pipe fitting 10 includes a main liquid transport tube 101, a first annular tube 102, and a first branch tube 103. An end of the main liquid transport tube 101 and an end of the first branch tube 103 are both attached to the first annular tube 102, other end of the main liquid transport tube 101 is connected to an end of the outlet one-way valve tube 8, and other end of the first branch tube 103 is used as the output end of the liquid transport composite pipe fitting 10 and is attached onto the bottom of the closed heat transfer cylinder 3. The reflux composite pipe fitting 11 includes a main reflux tube 111, a second annular tube 112, and a second branch tube 113. An end of the main reflux tube 111 and an end of the second branch tube 113 are both attached to the second annular tube 112, other end of the main reflux tube 111 is connected to an end of the reflux one-way valve tube 9, and other end of the second branch tube 113 is used as the input end of the reflux composite pipe fitting 11 and is attached onto the top of the closed heat transfer cylinder 3. The liquid transport composite pipe fitting 10 and the reflux composite pipe fitting 11 are structurally linked to the outlet one-way valve tube 8, the reflux one-way valve tube 9 and the capsular cold water component 4, to form a circulation channel for subsequent water circulation.

An outer side on a top of the reflux composite pipe fitting 11 is provided with a pressure-exerting rod piece 12 and a power output component 13, where an output structure of the power output component 13 is connected to an end of the pressure-exerting rod piece 12 in a transmission way, and other end of the pressure-exerting rod piece 12 extends to a surface in a middle of the inclined pressure-regulating plate 7 for adhesive connection.

The pressure-exerting rod piece 12 includes a curved support rod 121, a pressure-exerting sleeve roller 122, and a linkage rod 123. A side of the curved support rod 121 is attached to an inner side in a middle of the pressure-exerting sleeve roller 122 by means of a bearing, and other side of the curved support rod 121 is welded and fixed to an end of the linkage rod 123. A surface of the pressure-exerting sleeve roller 122 is adhered and connected to a surface in a middle of the inclined pressure-regulating plate 7. An outer side of the power output component 13 is covered with a semi-open protective shell. The power output component 13 includes a hydraulic rod 131 and a transition rod 132, where an output end of the hydraulic rod 131 is connected to an end of the transition rod 132 in a transmission way, and the transition rod 132 is used as an output structure of the power output component 13 and is connected to other end of the linkage rod 123 in a transmission way. A support seat is installed between a housing of the hydraulic rod 131 and a top of the machine room floor 2. The pressure-exerting rod piece 12 and the power output component 13 are combined to automatically exert pressure on the inclined pressure-regulating plate 7, and then the inclined pressure-regulating plate 7 synchronously exerts pressure on the capsular cold water component 4, allowing the cooling liquid inside the capsular cold water component 4 to flow in the circulation channel, to assist the closed heat transfer cylinder 3 in direct and targeted cooling of the data center 1 through water circulation.

An end of the transition rod 132 and the other end of the linkage rod 123 are both flange structures and are fixed by means of a screw; and other end of the transition rod 132 and the output end of the hydraulic rod 131 are both flange structures and are fixed by means of a screw. Detachable use of the two ends of transition rod 132 will provide conditions for independent use of the pressure-exerting rod piece 12.

A T-shaped rod is welded and fixed on a surface in a middle of the transition rod 132, where two ends of the T-shaped rod far away from the transition rod 132 are both flange structures, and the T-shaped rod is movably sleeved in the semi-open protective shell. By arranging the T-shaped rod, the power output component 13 may be allowed to link a plurality of pressure-exerting rod pieces 12 when needed, to perform synchronous operation of a plurality of power structures with a single power source. In this way, usage costs in cooling a plurality of data centers 1 can be reduced while the use effects are optimized.

An end of the linkage rod 123 is internally provided with a stepped hole, and an end of the stepped hole is provided with an internal thread. A surface at the other end of the linkage rod 123 is welded and fixed to a handle, and an outer side at an end of the linkage rod 123 is provided with a composite screw 14 and a lever bracket 15. An end of the composite screw 14 is in threaded connection inside the stepped hole, a top of the lever bracket 15 is provided with a positioning hole aligned with the composite screw 14, and a bottom of the lever bracket 15 is fixed on the machine room floor 2. The composite screw 14 is comprised of a nut 141 and a first threaded rod 142 and a second threaded rod 143 fixedly connected to two ends of the nut 141, respectively. The nut 141 is in threaded connection inside the stepped hole, and the first threaded rod 142 is movably sleeved in the stepped hole. The lever bracket 15 is combined with the composite screw 14 and is linked to the pressure-exerting rod piece 12, such that the pressure-exerting rod piece 12 can perform a pressure-exerting operation manually. In this way, overall performance of the device in coping with extreme situations can be improved.

The bottom of the lever bracket 15 is provided with an annular airbag 16, where a surface of the annular airbag 16 is glued and installed on the inner wall of the cooling trough. The annular airbag 16 is internally sleeved with a second reset spring, a top of the annular airbag 16 is sleeved with an intake one-way valve tube and an air transmission composite pipe fitting 17, where an output end of the air transmission composite pipe fitting 17 is connected to a heat transfer pipe 18. The heat transfer pipe 18 is fixedly sleeved inside the closed heat transfer cylinder 3, and two ends of the heat transfer pipe 18 both protrude to an outer side of the closed heat transfer cylinder 3. The air transmission composite pipe fitting 17 includes a main air transmission pipe 171, an arc-shaped pipe 172, and an air transmission branch tube 173. An end of the main air transmission pipe 171 and an end of the air transmission branch tube 173 are both attached to the arc-shaped pipe 172, other end of the main air transmission pipe 171 extends and attaches to an inner side on a top of the annular airbag 16, and other end of the air transmission branch tube 173 is used as an output end of the air transmission composite pipe fitting 17 and is attached onto a bottom of the heat transfer pipe 18. An inner side of the heat transfer pipe 18 is fixedly sleeved with a heat transfer sheet 19. Delivery of air inside the annular airbag 16 is achieved by means of extrusion deformation of the annular airbag 16 and the capsular cold water component 4, and synchronous air blast cooling of the cooling liquid inside the capsular cold water component 4 is achieved by means of the air transmission composite pipe fitting 17, the heat transfer pipe 18, and the heat transfer sheet 19, to further optimize the overall performance of the device.

Operating principles are as below. Regardless of whether it is in a manual operation or automatic operation, when the capsular cold water component 4 is extruded and deformed, it squeezes the annular airbag 16, such that the annular airbag 16 is synchronously deformed. Meanwhile, the air inside the annular airbag 16 is transported to the heat transfer pipe 18 through the air transmission composite pipe fitting 17 and achieve air blowing effects, to cool the heat transfer pipe 18. Next, auxiliary heat dissipation of the cooling liquid flowing inside the closed heat transfer cylinder 3 is performed by means of the heat transfer pipe 18 and the heat transfer sheet 19 through heat conduction.

It is to be noted that a relational term (such as a first or a second . . . ) herein is merely intended to separate one entity or operation from another entity or operation instead of requiring or hinting any practical relation or sequence exists among these entities or operations. Furthermore, terms such as “comprise”, “include” or other variants thereof are intended to cover a non-exclusive “include” such that a process, a method, a merchandise or a device comprising a series of elements not only includes these elements, but also includes other elements not listed explicitly, or also includes inherent elements of the process, the method, the merchandise or the device. In the accompanying drawings of the present disclosure, the filling pattern is only used for distinguishing the layers and does not make any other restrictions.

Although the embodiments of the present disclosure have been illustrated and described, those of ordinary skill in the art may appreciate that various changes, modifications, substitutions and variations may be made to these embodiments without departing from the principle or spirit of the present disclosure, and the scope of the present disclosure is limited by the claims and equivalents thereof.

What is claimed is:

1. A small water chiller for water circulation in a data center, comprising a data center (1) and a machine room floor (2), an auxiliary bracket touching the machine room floor (2) being mounted at a bottom of the data center (1); wherein a closed heat transfer cylinder (3) is nested inside a corner of the data center (1), a cooling trough positioned at a rear end of the data center (1) is provided on the machine room floor (2), inside the cooling trough there is sleeved with a capsular cold water component (4), a limit support plate (5), a support shaft (6), an inclined pressure-regulating plate (7), an outlet one-way valve tube (8), and a reflux one-way valve tube (9); the capsular cold water component (4) is internally sleeved with a first reset spring, and a bottom of the capsular cold water component (4) is provided with a receiving cavity, the receiving cavity is provided with a small water chiller for refrigerating a cooling liquid inside the capsular cold water component (4), and a middle of the support shaft (6) is attached into a side of the inclined pressure-regulating plate (7) by means of a bearing;
an end of the outlet one-way valve tube (8) and an end of the reflux one-way valve tube (9) are connected to a liquid transport composite pipe fitting (10) and a reflux composite pipe fitting (11), respectively; an output end of the liquid transport composite pipe fitting (10) and an input end of the reflux composite pipe fitting (11) extend and attach to a bottom and a top of the closed heat transfer cylinder (3), respectively; other end of the outlet one-way valve tube (8) and other end of the reflux one-way valve tube (9) extend and attach to two sides of the capsular cold water component (4), respectively; and
an outer side on a top of the reflux composite pipe fitting (11) is provided with a pressure-exerting rod piece (12) and a power output component (13), an output structure of the power output component (13) is connected to an end of the pressure-exerting rod piece (12) in a transmission way, and other end of the pressure-exerting rod piece (12) extends to a surface in a middle of the inclined pressure-regulating plate (7) for adhesive connection.

2. The small water chiller for water circulation in the data center according to claim 1, wherein a surface on a top of the capsular cold water component (4) is glued and fixed to a surface on a bottom of the limit support plate (5), two sides of the limit support plate (5) are fixed to an inner wall of the cooling trough by means of a screw; and a bottom surface of the capsular cold water component (4) is adhered and connected to an inner wall on a bottom of a demising trough.

3. The small water chiller for water circulation in the data center according to claim 1, wherein the liquid transport composite pipe fitting (10) comprises a main liquid transport tube (101), a first annular tube (102), and a first branch tube (103); an end of the main liquid transport tube (101) and an end of the first branch tube (103) are both attached to the first annular tube (102), other end of the main liquid transport tube (101) is connected to an end of the outlet one-way valve tube (8), and other end of the first branch tube (103) is used as the output end of the liquid transport composite pipe fitting (10) and is attached onto the bottom of the closed heat transfer cylinder (3).

4. The small water chiller for water circulation in the data center according to claim 1, wherein the reflux composite pipe fitting (11) comprises a main reflux tube (111), a second annular tube (112), and a second branch tube (113); an end of the main reflux tube (111) and an end of the second branch tube (113) are both attached to the second annular tube (112), other end of the main reflux tube (111) is connected to an end of the reflux one-way valve tube (9), and other end of the second branch tube (113) is used as the input end of the reflux composite pipe fitting (11) and is attached onto the top of the closed heat transfer cylinder (3).

5. The small water chiller for water circulation in the data center according to claim 1, wherein the pressure-exerting rod piece (12) comprises a curved support rod (121), a pressure-exerting sleeve roller (122), and a linkage rod (123); a side of the curved support rod (121) is attached to an inner side in a middle of the pressure-exerting sleeve roller (122) by means of a bearing, other side of the curved support rod (121) is welded and fixed to an end of the linkage rod (123), and a surface of the pressure-exerting sleeve roller (122) is adhered and connected to a surface in a middle of the inclined pressure-regulating plate (7).

6. The small water chiller for water circulation in the data center according to claim 5, wherein an outer side of the power output component (13) is covered with a semi-open protective shell, the power output component (13) comprises a hydraulic rod (131) and a transition rod (132), an output end of the hydraulic rod (131) is connected to an end of the transition rod (132) in a transmission way, the transition rod (132) is used as an output structure of the power output component (13) and is connected to other end of the linkage rod (123) in a transmission way, and a support seat is installed between a housing of the hydraulic rod (131) and a top of the machine room floor (2).

7. The small water chiller for water circulation in the data center according to claim 6, wherein an end of the transition rod (132) and the other end of the linkage rod (123) are both flange structures and are fixed by means of a screw; other end of the transition rod (132) and the output end of the hydraulic rod (131) are both flange structures and are fixed by means of a screw; a T-shaped rod is welded and fixed on a surface in a middle of the transition rod (132), two ends of the T-shaped rod far away from the transition rod (132) are both flange structures, and the T-shaped rod is movably sleeved in the semi-open protective shell.

8. The small water chiller for water circulation in the data center according to claim 5, wherein an end of the linkage rod (123) is internally provided with a stepped hole, an end of the stepped hole is provided with an internal thread, a surface at the other end of the linkage rod (123) is welded and fixed to a handle, an outer side at an end of the linkage rod (123) is provided with a composite screw (14) and a lever bracket (15), an end of the composite screw (14) is in threaded connection inside the stepped hole, a top of the lever bracket (15) is provided with a positioning hole aligned with the composite screw (14), and a bottom of the lever bracket (15) is fixed on the machine room floor (2), the composite screw (14) is comprised of a nut (141) and a first threaded rod (142) and a second threaded rod (143) fixedly connected to two ends of the nut (141), respectively, the nut (141) is in threaded connection inside the stepped hole, and the first threaded rod (142) is movably sleeved in the stepped hole.

9. The small water chiller for water circulation in the data center according to claim 8, wherein the bottom of the lever bracket (15) is provided with an annular airbag (16), a surface of the annular airbag (16) is glued and installed on the inner wall of the cooling trough, the annular airbag (16) is internally sleeved with a second reset spring, a top of the annular airbag (16) is sleeved with an intake one-way valve tube and an air transmission composite pipe fitting (17), an output end of the air transmission composite pipe fitting (17) is connected to a heat transfer pipe (18), the heat transfer pipe (18) is fixedly sleeved inside the closed heat transfer cylinder (3), and two ends of the heat transfer pipe (18) both protrude to an outer side of the closed heat transfer cylinder (3).

10. The small water chiller for water circulation in the data center according to claim 9, wherein the air transmission composite pipe fitting (17) comprises a main air transmission pipe (171), an arc-shaped pipe (172), and an air transmission branch tube (173); an end of the main air transmission pipe (171) and an end of the air transmission branch tube (173) are both attached to the arc-shaped pipe (172), other end of the main air transmission pipe (171) extends and attaches to an inner side on a top of the annular airbag (16), other end of the air transmission branch tube (173) is used as an output end of the air transmission composite pipe fitting (17) and is attached onto a bottom of the heat transfer pipe (18), and an inner side of the heat transfer pipe (18) is fixedly sleeved with a heat transfer sheet (19).
